(19) United States
(12) Patent Application Publication
(10) Pub. No.: US 2023/0392254 A1
(43) Pub. Date: Dec. 7, 2023

(54) INORGANIC POROUS COATINGS AND METHODS OF MAKING THE SAME

(71) Applicants: UCHICAGO ARGONNE, LLC, Chicago, IL (US); THE UNIVERSITY OF CHICAGO, Chicago, IL (US)

(72) Inventors: Elena Shevchenko, Lagrange, IL (US); Supratik Guha, Chicago, IL (US); Zhongbo Zhang, Morton Grove, IL (US); Cheng Ji, Chicago, IL (US)

(21) Appl. No.: 17/833,841

(22) Filed: Jun. 6, 2022

(51) Int. Cl. C23C 16/04; C09D 5/00; C09D 1/00; C23C 16/455; C23C 16/40

(52) U.S. Cl. CPC C23C 16/045; C09D 5/006; C09D 1/00; C23C 16/45553; C23C 16/403

(57) ABSTRACT

Polymers of intrinsic microporosity are used herein as polymer templates for forming mechanical robust inorganic porous coatings that can be beneficially used as anti-reflective coatings.

### STATEMENT OF GOVERNMENT SUPPORT

This invention was made with government support under Contract No. DE-AC02-06CH11357 awarded by the United States Department of Energy to UChicago Argonne, LLC, operator of Argonne National Laboratory. The government has certain rights in the invention.

### FIELD

The disclosure relates to inorganic porous coatings and methods of making the same, and more particularly to porous inorganic porous coatings produced from polymers of intrinsic microporosity and methods of making the same. Such coatings can be particularly useful as anti-reflective coatings.

### BACKGROUND

Anti-reflection coatings (ARCs) are widely used to reduce the light reflection at interfaces, and thereby enhance the transmittance of light. ARCs with low refractive indices are important for a broad range of applications such as solar cells, displays (mobile phones, computer and television screens), telescope lenses, cameras, and eyeglasses. The optical components in such devices are often made out of different types of glass with varying refractive indices, n, (e.g. fused glass (n=1.458), sapphire glass (n=1.768), Gorilla glass (n=1.50), ITO glass (n=1.827) at 630 nm).

According to the Fresnel equation, to minimize the reflectance of glass substrates in the visible range of the light spectrum, a single-layer ARC with n˜1.2-1.4 is required. The optimal thickness of the ARC for a given wavelength λ is ˜λ/4n at normal incidence for destructive interference, which leads to minimal reflectance over the spectral range around λ.

Bulk inorganic materials with n<1.4 are limited, and mainly restricted to fluorides. The MgF₂ with n˜1.38 in the visible range can lower the reflectance of each side of the float glass from 4.3% to 1%. However, MgF₂ thin film deposition involves the use of hydrofluoric acid or other aggressive precursors of fluorine. Additionally, MgF₂ is somewhat soluble in water (˜0.013 g/100 mL) and exposure to inorganic fluorides can be associated with health concerns. These factors reasonably impose some constrains on applicability of fluorides in fabrication of touchable devices and optical systems exposed to environment.

To achieve safe, non-toxic and stable coatings with lower refractive indexes, nanoporous thin films have been introduced for the fabrication of ARCs. According to effective medium theory, the refractive index of the thin composite film is determined by the fractions of different materials as long as the feature sizes are much smaller than the wavelength of the incident light. In the case of dry porous films, their refractive index will be determined by the refractive index of the inorganic material and air with the refractive index of 1. The higher porosity will be associated with the smaller refractive index. Therefore, proper control over the porosity is the key to nanoporous ARCs with the desired anti-reflectivity. Conventional techniques, including nanoporous thin film via polymer with porosities and lithography-produced nanostructure coatings, have also been researched for high-quality ARCs. However, porosity can compromise the mechanical properties of materials resulting in the increased brittleness, lower hardness and scratch resistance. Infiltration of block copolymers (BCPs) with inorganic precursors from the vapor phase (sequential infiltration synthesis, SIS) followed by polymer removal was previously shown to enable fabrication of low refractive index nanoporous all-inorganic thin films. However, as it is shown below the mechanical properties of such structures require improvement.

Multilayered ARCs have also been proposed. As compared to the single-layered ARCs, which can only reduce the reflection in a narrow spectral range, multilayered ARCs consisting of several alternating layers with different thicknesses and refractive indices can provide a better anti-reflection performance by minimizing the light reflection in a broad spectral range as a result of the destructive interference of wavefronts reflected at each interface. In turn, gradual decrease of refractive index (graded-index ARCs) allows avoiding a sharp transition between interfacing optical media resulting in minimal Fresnel reflection losses. The conventional techniques used to fabricate ARCs include layer-by-layer deposition of low index materials with vacuum coating techniques. This technology can produce ARCs with industrial-level optical and mechanical performance. However, the significant drawback is the resulting high cost for the high-quality multi-layer structures.

### SUMMARY

In accordance with the disclosure, a process for forming an inorganic porous coating on a substrate includes forming a polymer template having a plurality of pore comprising applying a thin film of a polymer of intrinsic microporosity on the substrate; and performing an infiltration cycle. The infiltration cycle includes infiltrating the pores of the polymer template with a first vapor comprising a coating precursor material, wherein the coating precursor material is a precursor for forming an inorganic coating material and the coating precursor material binds to functional groups of the polymer template, and infiltrating the pores of the polymer template having the coating precursor material bound thereto with a second vapor comprising precursor reactant vapor, wherein the bound coating material precursor reacts with the precursor reactant to form the inorganic coating material arranged to form the porous inorganic coating.

A process for forming a multi-layer coating comprising: performing the process of the preceding paragraph to form a first coating layer and repeating the process to form two or more additional coating layers on the first coating layer.

In accordance with the disclosure, a porous inorganic multilayer coating formed on a substrate can include a first porous coating layer disposed on the substrate, the first porous coating layer comprising an inorganic oxide material and comprising a plurality of pores distributed substantially uniformly through the coating, the pores having an average pore size of less than about 10 nm as measured by electron microscopy; and a second porous coating layer formed from a block copolymer template arranged on the coating, wherein the second porous coating layer formed from the block copolymer comprises pores having a tubular pore structure. The first coating layer can be formed using a polymer of intrinsic porosity polymer template.

Coatings of the disclosure can be useful as anti-reflective coatings. Coatings of the disclosure can also or alternatively be useful as protective coatings. Coatings of the disclosure have been observed to have beneficial properties, including, but not limited to, improved performance as anti-reflective coatings, high hardness, and/or resistance to scratching.

Coatings of the disclosure and multi-layer coatings of the disclosure can be formed on any substrates. For example, the coatings and multi-layer coatings of the disclosure can be formed on substrates having metal oxide layers.

### BRIEF DESCRIPTION OF THE DRAWINGS

FIG. 1A is an AFM image of an as-spin-coated PIM-1 template used in a process in accordance with the disclosure;

FIG. 1B is an AFM image of the PIM-1 template of FIG. 1A after methanol treatment for 1 h at 55° C.;

FIG. 1C is a graph showing QCM data on the PIM-1 template before and after methanol treatment;

FIG. 1D is a graph showing the FTIR spectra of the as-spin-coated PIM-1 and the PIM-1 template after infiltration with AlOₓ;

FIG. 1E is a graph showing the refractive indices as measured using ellipsometry of nanoporous AlOₓ films in accordance with the disclosure, obtained via infiltration of PIM-1 (AlOₓ^{PIM}) and conventional films obtained using a block copolymer PS(79)-PVP(36.5) (AlOₓ^{BCP});

FIG. 2 is a depiction of the steps involved in the fabrication of single-layer and double-layered AlOx ARCs using PIM-1. PIM-1 serves as a template for the synthesis of the porous AlOx (Layer 1). More porous structures can be deposited on the top of Layer 1 using BCP as a template for the formation of more porous double-layered structures;

FIG. 3A is an SEM image of a single 80 nm thin AlOₓ layer formed in accordance with the disclosure after 10 SIS cycles using a PIM-1 polymer template (AlOₓ^{PIM}, Layer 1);

FIG. 3B is an SEM image of a 105 nm thin AlOₓ layer formed as a result of 10 SIS cycles on PS(79)-PVP(36.5) (AlOₓ^{BCP}, Layer 2);

FIG. 3C is an SEM image of the double-layer AlOₓ coating (AlOₓ^{PIMBCP}) in accordance with the disclosure;

FIG. 3D is an SEM image showing the interface between AlOₓ layers with different porosities in the double-layer AlOₓ ARC (bottom and top layers were ˜80 and 105 nm respectively);

FIG. 3E is a graph showing SAXS data obtained for AlOₓ layers shown in FIGS. 3A-3D;

FIG. 4A is a graph of the reflectance of a single (AlOₓ^{PIM}) coating in accordance with the disclosure and a graded-index double-layer (AlOₓ^{PIM/BCP}) coating in accordance with the disclosure deposited sapphire glass;

FIG. 4B is a graph of the transmittance of a single (AlOₓ^{PIM}) coating in accordance with the disclosure and a graded-index double-layer (AlOₓ^{PIM/BCP}) coating in accordance with the disclosure deposited sapphire glass;

FIGS. 4C and 4D are optical micrographs visualizing performance of the porous ARCs. The images were taken at normal incidence and at ˜45° angle (top and bottom, respectively). Images shown in (4D) were taken at ˜45° angle to the substrate;

FIG. 4E shows contact angle measurements (e) on sapphire and sapphire coated with graded-index double-layered (AlOₓ^{PIM/BCP}) after hexamethyldisilazane (HMDS) treatment;

FIG. 5A is a graph of the reflectance of a single (AlOₓ^{PIM}) coating in accordance with the disclosure and a graded-index double-layer (AlOₓ^{OIM/BCP}) coating in accordance with the disclosure deposited Gorilla glass;

FIG. 5B is a graph of the transmittance of a single (AlOₓ^{PIM}) coating in accordance with the disclosure and a graded-index double-layer (AlOₓ^{PIM/BCP}) coating in accordance with the disclosure deposited Gorilla glass;

FIG. 5C shows optical images of Gorilla glass sample with graded-index double-layered (AlOₓ^{PIM/BCP}) coatings obtained at normal incidence (top image) and at ˜30° angle (bottom image). FIG. 5C (bottom image) shows the elimination of the reflection at the coated substrate while the reflection of the fluorescent light tube is pronounced at the surrounding uncoated substrates;

FIG. 6A is a graph showing the exerted load vs nanoindentation depth of a graded-index double-layer 185 nm coating (AlOₓ^{PIM/BCP}) deposited on different substrates (Si and sapphire);

FIG. 6B is a graph showing the thin film hardness vs nanoindentation depth of a graded-index double-layer 185 nm coating (AlOₓ^{PIM/BCP});

FIG. 6C is a graph showing the scratch load vs the scratch position during the nano scratch test of a graded-index double-layer 185 nm coating (AlOₓ^{PIM/BCP}). The critical markers show the point when the pinhead is lifted off the surface;

FIG. 6D is a graph showing the vertical scratch profile vs the scratch position during the nano scratch test of FIG. 6C;

FIG. 6E is a graph showing a comparison of the exerted nanoindentation depth of AlOₓ^{PIM} (Layer 1 in double-layer ARC) and AlOₓ^{BCP} (Layer 2 in double-layer ARC) on Si;

FIG. 6F is a graph showing a comparison of the thin film hardness vs nanoindentation depth of AlOₓ^{PIM} (Layer 1 in double-layer ARC) and AIOₓ^{BCP} (Layer 2 in double-layer ARC) on Si;

FIG. 6G is a graph showing a comparison of the scratch load vs the scratch position during the nano scratch test of AlOₓ^{PIM} (Layer 1 in double-layer ARC) and AIOₓ^{BCP} (Layer 2 in double-layer ARC) on Si. The critical markers show the point when the pinhead is lifted off the surface;

FIG. 6H is a graph showing the vertical scratch profile vs the scratch position during the nano scratch test of FIG. 6G. The comparison shows that the AlOₓ^{PIM} layer has much higher hardness and scratch resistance as compared to AlOₓ^{BCP};

FIG. 7A is an AFM image and feature height graph of as spin-coated PIM-1 template;

FIG. 7B is an AFM image and feature height graph of the PIM-1 template after methanol treatment for 1 h at 55° C.;

FIG. 8A is a graph showing the XPS results of a PIM-1 template;

FIG. 8B is a graph showing the XPS results of the PIM-1 template after methanol treatment for 1 h at 55° C., which demonstrate the increased intensity of Cl S signal at 286.5 eV and O1s at 531.8 eV in the corresponding XPS spectra obtained on methanol treated PIM-1 films;

FIG. 9 is a graph showing Energy Dispersive X-ray Spectroscopy (EDS) measurement results on the double-layer coating in accordance with the disclosure on Si substrate showing the complete removal of the polymer;

FIG. 10 is an SEM overview image (top image) of an AlOₓ^{PIM} coating in accordance with the disclosure delaminated from the Si substrate. The delamination took place at the area of the Si contaminated with grease. The images on the bottom show uniform distribution of the elements across the film;

FIG. 11 is an SEM overview image (on the left) of the graded index double-layer AlOₓ coating. The arrows point to the areas where AlOₓ in the AlOₓ^{PIM} (Layer 1) has small dimples formed most likely after removal of the air trapped during the PIM-1 spin-coating after thermal annealing. The impact of such imperfections is negligible. SEM image (on the left) showing a scratch formed as a result of intensive mechanical scratch with a needle showing the interface between AlOₓ^{PIM} and AlOₓ^{BCP} (Layer 1 and Layer 2, respectively). This image also indicates that dimples in AlOₓ^{PIM} layer do not damage its mechanical performance;

FIG. 12A is a photograph of a commercially available lens having an anti-reflective coating;

FIG. 12B is a graph showing exerted load vs. nanoindentation depth and thin film hardness v nanoindentation depth for the commercial lens of FIG. 12A;

FIG. 12C is a graph showing scratch load vs the scratch position during the nano scratch test of the commercial lens of FIG. 12A. The critical markers show the point when the pinhead is lifted off the surface;

FIG. 12D is a graph showing the vertical scratch profile vs the scratch position during the nano scratch test of FIG. 12C. Compared with FIG. 4 in the context, the hardness of this commercial ARC is comparable with the nanoporous double-layer coating in accordance with the disclosure, but the resistance against scratch is only one-third of the coating in accordance with the disclosure;

FIG. 13A is a graph showing the exerted load vs nanoindentation depth of a double-layer coating in accordance with the disclosure on Gorilla glass;

FIG. 13B is a graph showing the thin film hardness vs nanoindentation depth of a double-layer coating in accordance with the disclosure on Gorilla glass;

FIG. 13C is a graph showing the scratch load vs the scratch position during the nano scratch test of a double-layer coating in accordance with the disclosure on Gorilla glass. The critical markers show the point when the pinhead is lifted off the surface;

FIG. 13D is a graph showing the vertical scratch profile vs the scratch position during the nano scratch test of FIG. 13C. The lower hardness and scratch resistance of double-layer coating deposited on Gorilla Glass was attributed to the lower adhesion of the films to the substrate as a result of the trapped air during spin coating of the polymer;

FIG. 14A is a graph of the reflectance from an uncoated sapphire glass and sapphire coated with a double-layer coating in accordance with the disclosure, measured with normal incidence;

FIG. 14B is a graph showing the transmittance from uncoated sapphire glass and then coated with a double-layer coating in accordance with the disclosure;

FIG. 14C is a graph showing the reflectance from the uncoated Gorilla glass and Gorilla glass coated with a double-layer coating in accordance with the disclosure, measured with normal incidence; and

FIG. 14D is a graph showing the transmittance from uncoated Gorilla glass and then coated with a double-layer coating in accordance with the disclosure.

### DETAILED DESCRIPTION

The coatings and methods of the disclosure utilize polymers of intrinsic microporosity as a degradable three-dimensional scaffold or template to be infiltrated with metal oxide precursors to ultimately result in a fully inorganic metal oxide film with a desired porosity. Conventionally, PIMs have studied for their potential for CO₂ adsorption and have only been infiltrated with metal oxide networks for the mechanically reinforcing the PIM structure. It has been surprisingly found that PIMS could be successfully used as a polymer template to form a porous inorganic metal oxide film with excellent properties, such as mechanical and/or anti-reflective properties that are tunable with pore size and density.

Porous inorganic coatings in accordance with the disclosure are formed using a polymer of intrinsic microporosity as a polymer template. The coatings of the disclosure can be used as single layer of or can be incorporated into multilayer structures including other coating layers, including nonporous and/or porous coatings formed by other methods and/or multiple layers of coatings in accordance with the disclosure. It has been beneficially found that the coatings formed using the polymers of intrinsic microporosity as the polymer template have uniform pore distribution and size throughout the coating layer. Further, use of porous inorganic coatings formed using polymers of intrinsic microporosity as a polymer template in combination with other porous coating, such as conventional block copolymer formed coatings, can allow for tuned pore structures and gradients of porosity. This can be beneficial in various application, for example, in use of the coatings as anti-reflective coatings.

The inorganic coating formed in accordance with the disclosure whether single layer or part of a multi-layer coating structure can advantageously be very thin layers, yet maintain good mechanical properties such as high hardness and scratch resistances values. For example, the coating can have a thickness of less than 200 nm. The ability to provide thin yet mechanically robust coatings with high porosity is advantageous particularly for optical applications such as lenses and substrates for electronic displays. Coatings of the disclosure can be incorporated into multi-layer coating structures having any suitable number of layers. The coatings of the disclosure can be incorporated as one or more layers of the coating structures. The multi-layer structures can include any combination of one or more of non-porous coating layers, conventional porous coating layers, and layers formed by coatings of the disclosure.

Single layer coatings of the disclosure can have a refractive index of about 1.41, for example, making them well suited for use with high refractive index glasses, such as those used in optical systems. Single-layer coatings of the disclosure were demonstrated to provide a reduction of the Fresnel reflections of sapphire to as low as 0.1% at 500 nm with deposition of the coating on only one side of the substrate. Multi-layer structures using coating layers in accordance with the discourse and a block copolymer template formed coatings provided a graded-index coating that was demonstrated to have a reduction of Fresnel reflections under normal illumination to below 0.5% in a broad spectral range with 0.1% reflection at 700 nm. The double-layer coatings tested surprisingly demonstrated such beneficial optical performance while maintain a very thin coating thickness layer. For example, the total thickness of the double-layer coating demonstrating these properties was about 200 nm.

The coatings of the disclosure generally have good mechanical properties, with high hardness and scratch resistance properties. For example, coatings of the disclosure can have a hardness that is improve as compared to bulk silica glass. For example, the hardness can be greater than about 6 GPa. For example, in some instances the coating can improve the hardness as compared to the substrate. The coatings of the disclose can also demonstrate good scratch resistance, having an improved scratch resistance as compared to porous anodic aluminum oxide coatings, for example. These properties make the coatings of the disclosure useful as protective coatings or layers.

As shown in the examples, the tested coatings of the disclosure also were found to be mechanically robust. The coatings tested were found to have a hardness of about 7.5 GPa and excellent scratch resistance. The maximum reached load during scratch testing was 13 mN with a scratch depth of only about 130 nm. This was surprisingly good scratch properties, in particular, given that the coatings are highly porous films. For example, the tested double layer coatings had porosity of 50% (single layer) and 85% (double-layer) porosities.

A porous coating formed from a polymer of intrinsic microporosity polymer template in accordance with the disclosure is formed of an inorganic material and has a plurality of pores distributed substantially uniformly throughout the coating. The pores have an average pore size of less than about 10 nm. The pore size can be measured, for example, by electron microscopy.

Single layer coatings formed using polymer of intrinsic microporosity polymer templates can have a thickness of about 20 nm to about 100 nm. For example, the coating can have a thickness of up to 200 nm.

The inorganic coating can be formed from metal oxides and/or metal hydroxides. For examples, the metal oxide can be, for example, an oxide and/or a hydroxide of aluminum. The inorganic coating material can include a compound of MOₓ, wherein M is Al, Cr, Fe, Co, Ni, Pb, Zr, Ru, Rh, Sm, Ti V, Mo, W, or Zn.

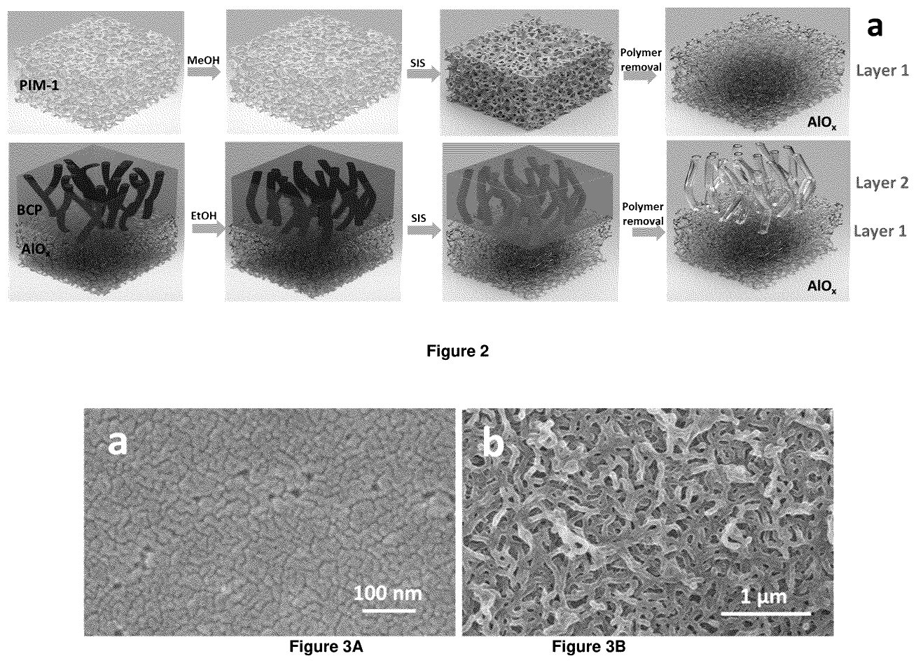

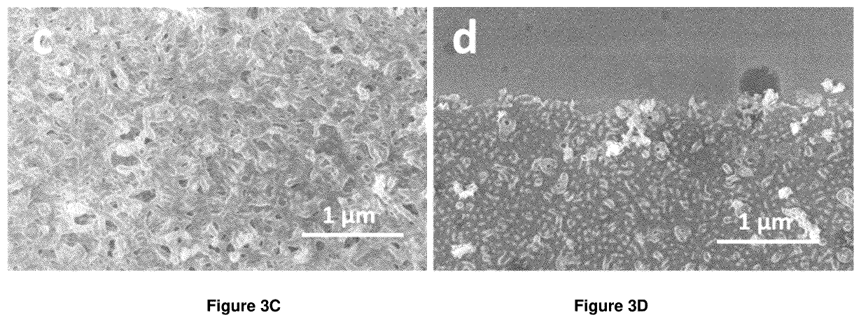

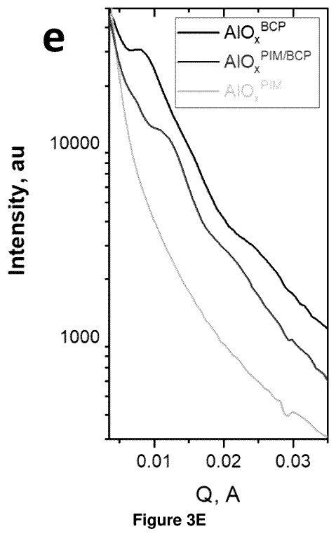

Referring to FIGS. 2 and 3A, it has been surprisingly and beneficially found that porous coatings formed in accordance with the disclosure using polymers of intrinsic microporosity as the template material have uniformly distributed pores throughout the coating. The pores are also uniformly shaped. In general, pores of the coatings of the disclosure formed with polymers of intrinsic microporosity polymer templates can be substantially spherically shaped. The coating can have a porosity of at least about 10%, at least about 15%, at least about 20%, at least about 25%, at least about 30%, at least about 35%, at least about 40%, at least about 45% or at least about 50%. For example, the porosity of a single layer coating or a coating layer of a multi-layer coating in accordance with the disclosure can be about 25% to about 50%. For example, the porosity of a single layer coating or a coating layer in accordance with the disclosure formed using a PIM template can be about 10% to about 60%.

The coatings of the disclosure have pores with an average diameter as less than about 10 nm. For example, the average diameter can be about 1 nm to about 10 nm, about 1 nm to about 5 nm, about 3 nm to about 8 nm, or about 1.2 nm to about 5 nm. Other suitable average pore diameters can be about 1, 1.2, 1.4, 1.6, 1.8, 2, 2.2, 2.4, 2.6, 2.8, 3, 3.2, 3.4, 3.6, 3.8, 4, 4.2, 4.4, 4.6, 4.8, 5, 5.2, 5.4, 5.6, 5.8, 6, 6.2, 6.4, 6.6, 6.8, 7, 7.2, 7.4, 7.6, 7.8, 8, 8.2, 8.4, 8.6, 8.8, 9, 9.2, 9.4, 9.6, 9.8, or 10 nm.

The coatings can be formed on any suitable substrate material. For example, the substrate can be silicon, glass, or sapphire. For example, the substrate can be Gorilla glass. For example, the substrate can be bendable glass. For example, the substrate can be conductive glass, such as ITO glass or AZO glass. The substrate can have layers present on the substrate onto which the coatings of the disclosure are formed. For example, the substrate can have a metal oxide layer present on the substrate and the coating of the disclosure can be formed on top of the metal oxide layer. Substrates of the disclosure can have other optical coatings present as well on to which the coating of the disclosure can be formed. In such arrangements, the coatings of the disclosure can serve as a protective layer to the underlying optical coating. Coatings of the disclosure can be useful as antireflective coatings while allowing underlying substrates to maintain good optical and electronic properties. As such, the coatings can be useful for substrate used as electronic displays. The coating of the disclosure in any of these foregoing applications can be an anti-reflective coating and/or a protective coating.

Coatings of the disclosure can maintain and/or improve transparency of the substrates on which they are coated. Coatings of the disclosure formed from polymer templates using polymers of intrinsic microporosity can reduce reflectance to below 1%. For example, as demonstrated in the examples below, the coatings of the disclosure can reduce reflectance to below 0.1%.

The coatings and multi-layer coating of the disclosure can be transparent to light between wavelengths of 400 nm to 800 nm with a transmissivity of more than 80%, and/or transparent to light between wavelengths of 300 nm to 400 nm with a transmissivity of more than 80%, and/or transparent to light between wavelengths of 800 nm to 2000 nm with a transmissivity of more than 80%.

Coatings formed using polymer of intrinsic microporosity polymer templates can be used in combination with other coatings to form a multi-layer coating. The multi-layer coating can be a gradient index coating, providing a gradient of changes in refractive index throughout the thickness of the coating. For simplicity of the discussion, a double-layer structure will be described primarily herein. However, multi-layer coatings are also contemplated here and can be formed using the principles and processes described with respect to the double layer coatings. Any number and arrangement of porous coating layers formed using polymer of intrinsic material polymer templates and other porous and nonporous coating layers can be used. Multi-layer coatings can have a total thickness of up to 1 microns, with individual coating layers having the same or different thicknesses.

A double-layer coating in accordance with the disclosure can include at least a first layer arranged on the substrate and a second layer arranged on the first layer. The first layer can be a porous inorganic coating formed using a polymer of intrinsic microporosity polymer template. The second layer can be, for example, a porous coating formed using a block copolymer polymer template. Other conventional porous coating methods can also be used for forming the second layer. Other arrangements of coating layers such that the coating formed using the polymer of intrinsic porosity polymer template is not directly adjacent to the substrate are also contemplated herein.

Referring to FIG. 2, a coating layer, for example the second coating layer, when formed from a block copolymer polymer template can have tubular shaped pores that extend through the thickness of the coating.

The various coating layers of a multilayer coating can be formed with the same inorganic material or with different inorganic materials.

In accordance with the disclosure, a process for forming an inorganic porous coating or coating layer on a substrate includes forming a polymer template having a plurality of pores on the substrate using a polymer of intrinsic microporosity and infiltrating the pores of the polymer template with an inorganic material to form the coating. The polymer template can be formed by forming a thin film of a polymer of intrinsic microporosity on the substrate. The thin film can optionally be treated with a solvent. It has been observed that infiltration of the precursor materials is improved after solvent treatment. The process further includes performing one or more infiltration cycles to deposit the coating material within the pores of the polymer template. The infiltration cycle includes infiltrating the pores of the polymer template with a first vapor phase comprising a coating precursor material, wherein the coating precursor material is a precursor for forming an inorganic coating material. The coating precursor material binds to functional groups of the polymer template. The cycle then includes infiltrating the pores of the polymer template having the coating precursor material bound thereto with a precursor reactant vapor, wherein the bound coating material precursor reacts with the precursor reactant vapor to form the inorganic coating material arranged to form the porous inorganic coating. The resulting coating is a coating in accordance with the disclosure formed from the polymer of intrinsic microporosity polymer template.

Processes of the disclosure as detailed below can further include forming one or more additional coatings or coating layers on this coating and/or forming this coating one more of more preexisting or preformed coating layers. The additional coatings layers resulting in the multi-layer structure can be performed by repeating the process to provide layers of coatings of the disclosure and/or can include other known coating layer types, including non-porous and conventional porous coating layers.

The process can further include removing the polymer template formed from the polymer of intrinsic microporosity to leave only the inorganic porous coating on the substrate. The polymer template can be removed, for example, by annealing and/or ozone etching.

One or more infiltration cycles can be performed to build the coating precursor material bound to the polymer template. A gas purge can be performed between the infiltration cycles. The infiltration process can be repeated any number of cycles. For example, the infiltration can be repeated from 1 to 20 cycles. The infiltration can be completed using any chemical vapor deposition techniques known. For example, atomic layer deposition processes can be used for the infiltration.

Any known polymer of intrinsic microporosity can be used. Such polymers are commonly known in the art as polymers that do not require a network of covalent bonds in order to demonstrate microporosity. Intrinsic microporosity in polymers is defined as a continuous network of interconnected intermolecular voids, which forms as a direct consequence of the shape and rigidity of the component macromolecules. Any suitable polymers of intrinsic microporosity can be used, such as those disclosed in, McKewon, Polymers of Intrinsic Microporosity, Intl. Scholarly Research Network Materials Science, Article ID 513986 (2012). For example, the polymer can be polymer of intrinsic microporosity 1 (PIM-1). PIM-1 has pores smaller than 2 nm and high gas permeability.

The thin film of the polymer of intrinsic microporosity can have a thickness of about 20 nm to about 200 nm. The thin film can be deposited using any known methods, such as, but not limited to dip coating, spin coating, spray coating, and doctor blading.

The solvent treatment can be any solvent that does not dissolve the polymer of intrinsic microporosity. For example, the solvent can be one or more of methanol, ethanol, acetone, and toluene. The solvent treatment can be performed by immersing the substrate having the thin film of polymer of intrinsic microporosity in the alcohol for a time of about 5 min to about 2 hours, about 10 min to about 45 min, about 30 min to about 1 hour, about 1 hour to about 2 hours. Other suitable times include about 5, 10, 15, 20, 25, 30, 35, 40, 45, 50, 55, 60, 65, 70, 75, 80, 85, 90, 95, 100, 105, 110, 115, or 120 min.

The coating precursor material is one or more of trimethylaluminium (TMA), diethylzinc, tris(dimethylamido)silane, tetrakis(dimethylamido)zirconium, titanium tetrachloride, titanium tetraisopropoxide, nickel(II) acetylacetonate, palladium(II) hexafluoroacetylacetonate, copper bis(2,2,6,6-tetramethyl-3,5-heptanedionate, metallocenes ((C₅H₅)₂M where M can be, for example, Cr, Fe, Co, Ni, Pb, Zr, Ru, Rh, Sm, Ti, V, Mo, W, or Zn), and half-metallocene compounds (e.g., (C₅H₅)M(CH₃)₃ and (CH₃C₅H₄)M(CH₃), wherein M can be, for example, Cr, Fe, Co, Ni, Pb, Zr, Ru, Rh, Sm, Ti, V, Mo, W, or Zn).

The precursor reactant can be H₂O in the vapor phase.

The process of the disclosure can further include removing the polymer template. The polymer template can be removed by any suitable method, such as, but not limited to thermal annealing and/or ozone etching.

Processes of the disclosure can be used for forming multi-layer coatings. The multilayer coating can include one or more layers of a coating formed from a polymer of intrinsic microporosity polymer template and the process for forming such a coating can be used in forming this layer of a multi-layer coating. The process can be repeated to form multiple coating layers using the polymer of intrinsic microporosity polymer template process described herein. The process can further include forming additional coating layers by other methods known in the art, such as porous coating formed using block copolymer templates, and nonporous coatings.

For example, a double layer coating can be formed by first forming a first porous inorganic coating layer using the polymer of intrinsic microporosity template on the substrate and then forming a second coating layer on top this inorganic coating by depositing a block copolymer onto the first coating layer as a thin film. The block copolymer thin film can then be exposed to a solvent treatment to thereby form a block copolymer polymer template having a plurality of pores. The plurality of pores can be infiltrated with a coating precursor material in a vapor phase, wherein the coating precursor material is a precursor for forming an inorganic coating material. The coating precursor material can be the same or different than the coating precursor material used in forming the first coating. The process then further includes infiltrating the pores of the block copolymer polymer template having the coating precursor material therein reacts with a precursor reactant vapor, wherein the coating material precursor reacts with the precursor reactant to form the inorganic coating material arranged to form the second porous inorganic coating layer on the first porous inorganic coating, the second porous inorganic coating layer having tubular shaped pores.

The polymer template formed with the polymer of intrinsic microporosity can be removed before forming the thin film of the block copolymer. The process can also include removing the block copolymer polymer template after forming the second coating layer.

The process can include any number of repeated coating steps using any combination of coating layers formed with conventional templates and coatings in accordance with the disclosure with polymers of intrinsic microporosity as the polymer template.

The coatings and multi-layer coatings of the disclosure can be used as anti-reflective coatings and/or as protective coating or coating layers for lens or other coated substrates.

### EXAMPLES

Silicon, sapphire, and Gorilla Glass were used as substrates. Silicon substrates with 300 nm thermal oxide were purchased from Silicon Valley Microelectronics, Inc. Half-inch sapphire glass windows were purchased from Meller Optics. Gorilla Glass substrates were purchased from Abrisa Technologies.

The polymer of intrinsic microporosity (PIM-1) was synthesized in DMAc at 160° C. following the procedure reported in Du, N.; Robertson, G. P.; Song, J.; Pinnau, I.; Thomas, S.; Guiver, M. D., Polymers of Intrinsic Microporosity Containing Trifluoromethyl and Phenylsulfone Groups as Materials for Membrane Gas Separation. Macromolecules 2008, 41 (24), 9656-9662. Dimethylacetamide (DMAc, Sigma Aldrich) and anhydrous potassium carbonate (K₂CO₃, Sigma-Aldrich) were used as received. 5,5′,6,6′-Tetrahydroxy-3,3,3′,3′-tetramethylspirobisindane (TTSBI, Sigma-Aldrich) was purified by crystallization from methanol. Tetrafluoroterephthalonitrile (TFTPN, Sigma-Aldrich) was purified by vacuum sublimation at 150° C. under an inert atmosphere. The block copolymer poly(styrene-block-4-vinylpyridine) (PS-P4VP) (specifically in this study (PS(79)-PVP(36.5)) was purchased from Polymer Source, Inc.

Coatings in accordance with the disclosure were deposited onto the substrate by first depositing a polymer film, then solution treating the deposited polymer, and infiltrating the polymer templates with alumina precursors. The substrates were cleaned using a cleaning process that included sonication in DI water (2 min) followed by sonication in acetone (2 min) and in isopropanol (2 min).

In particular, dry PIM-1 powder was dissolved in anhydrous chloroform with a concentration of 20 mg/ml. After dissolution, the polymer solution was filtered through a PTFE 0.45 μm pore size filter and spin-coated onto the clean substrate at 2000 rpm.

The substrates with the deposited polymer coatings were immersed in methanol and heated to 55° C. for about 1 hour, and then kept at room temperature overnight in a fume hood. After immersion, the samples were dried under nitrogen gas flow and used for infiltration with inorganic precursors from the vapor phase immediate.

Infiltration with alumina precursors was preformed using a sequential-infiltration-synthesis (SIS) method. A GEMStar Thermal atomic layer deposition (ALD) system was used. Infiltration, however, could be completed using other chemical vapor deposition systems. Trimethylaluminum (TMA) and H₂O were used as gas-phase precursors. In the first half of a SIS cycle (about 400 s), the TMA vapors were allowed to infiltrate into the polymer template, selectively binding to the functional groups of the polymer. The selectively bound precursors then reacted with water vapor locally producing AlOₓ in the next half of the synthesis cycle (about 120 s). At the end of the SIS cycle, the unreacted gases were purged out of the chamber. The procedure was repeated 10 times. The infiltration was performed at 90° C. For double-layer ARC coatings in accordance with the disclosure, 10 cycles of SIS were performed both on PIM and BCP templates to obtain the layers, Layer 1 and Layer 2, respectively.

After SIS, the samples were annealed at 500° C. for 1 to 3 hours to remove the polymer template under airflow in the quartz tube in a Thermolyne 21100 Tube Furnace.

Hexmethyldisilazane (HMDS) treatment was performed using YES-3/5TA at 150° C., 1 Torr pressure, and 3 cycles of N₂ and HMS purging for 5 min.

Double layer anti-reflective coatings were prepared by forming a coating using conventional block copolymer techniques on top of the porous coating in accordance with the disclosure. The block copolymer thin films were prepared using a dry PS(79)-PVP(36.5) powder. The powder was dissolved in toluene to obtain 13 mg/ml. After dissolution, the polymer solution was filtered through a PTFE 0.45 μm pore size filter and spin-coated onto the clean substrate at 2000 rpm to provide a 50 nm BCP film on top of the porous AlOₓ coating formed in accordance with the disclosure. The BCP coated substrate was immersed in ethanol heated to 75° C. for 2 hours as a non-solvent swelling treatment of the BCP to increase the infiltration depth of the polymer and porosity of the final metal oxide thin film. 10 SIS cycles were performed to infiltrate the BCP polymer with alumina precursors; after which the polymer was removed by a 1 hour thermal anneal.

Characterization: Horiba Jobin Yvon UVISEL Spectroscopic Ellipsometer was used to measure the film thickness, porosity, and refractive index of the nanoporous thin film. Refractive indices were measured for at least 5 samples for each type of samples. The Fourier-transform infrared spectroscopy (FTIR) data were measured through Nicolet 6700 FTIR Spectrometer.

Quartz crystal microbalance (QCM) experiments were conducted for the quantitative analysis of the effect of methanol treatment on the PIM-1 using an SRS QCM200 controller. PS(79)-PVP(36.5) and PIM-1 films were deposited on the titanium QCM substrates via spin-coating of the corresponding polymer solutions.

Atomic force microscopy (AFM) analysis of the coating morphology was performed with a Bruker Multimode AFM in the tapping mode using the silicon tip (0.5 Hz scanning speed). The scanning electron microscopy (SEM) images were obtained using a JEOL JSM-7500F microscope. Film reflectance was measured by a Filmetrics F40 thin film analyzer. The transmittance of the samples was characterized using UV-VIS spectrophotometer Cary-50. The FTIR analysis was performed using Nicolet 6700 spectrometer. Contact angle measurements were conducted using a Kruss DSA100 drop shape analyzer. The mechanical properties of the thin films were characterized by KLA iNano nanoindenter. Fused silica reference material was tested for instrument verification. The hardness tests were performed with the Berkovich tip. The scratch tests were performed with a conical tip with a radius of 5 μm by applying continuously increasing load on the film as the indenter moves along the surface of the substrate with velocity of 20 μm/s layer. The ramp-load starts at 0.04 mN and ends upon reaching of a load necessary to cause some identifiable film failure (critical load) or until reaching 20 mN if the films does not deform. All scratch tests were run using the same parameters to compare the critical load values from different samples more accurately. The critical load is automatically determined by the instrument using acoustic emission feedback picked by a piezoelectric detector arranged next to the indenter. A critical load is defined as the load value at which the acoustic emission suddenly increases. Depth profiles of the scratch vectors are also recorded and analyzed. SAXS data were collected at beamline 12-ID-B at Advanced Photon Source (APS). The X-ray photoelectron spectroscopy (XPS) analysis was performed using the PHI 5000 Versaprobe spectrometer with monochromatic 1486.6 eV Al Kα radiation.

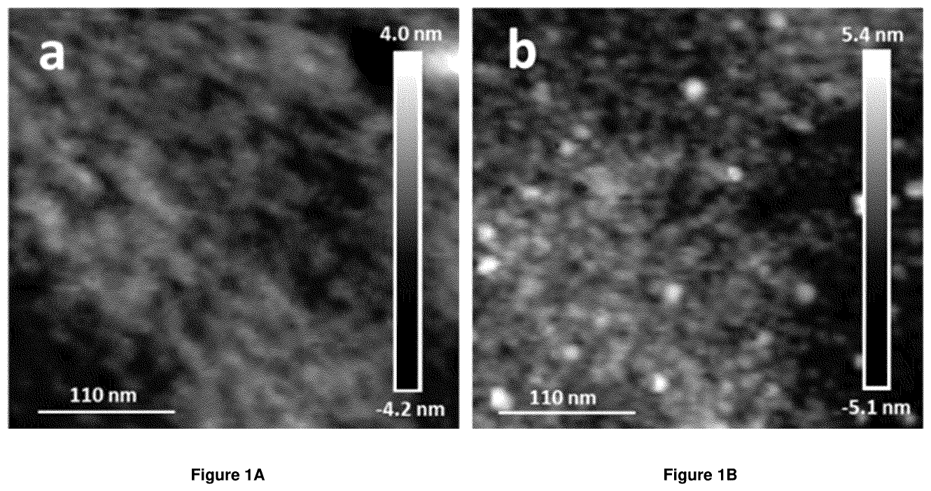

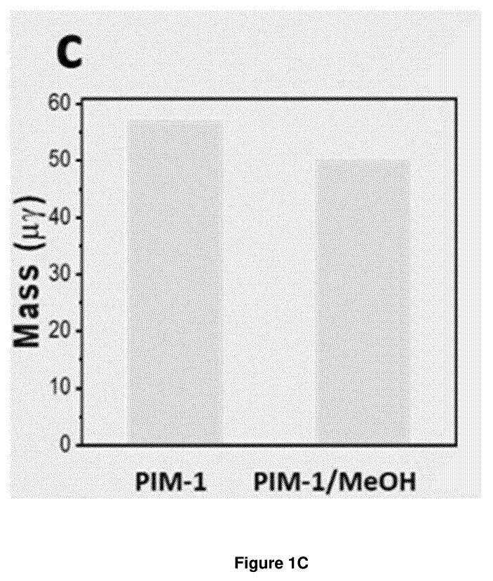

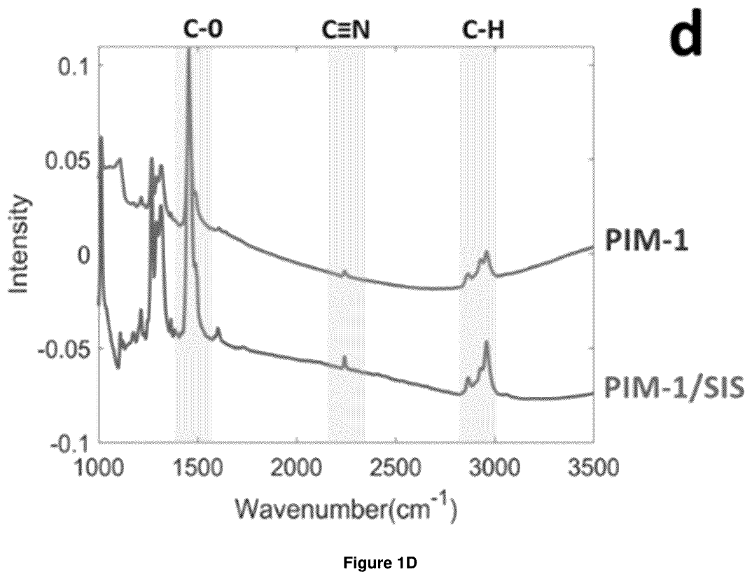

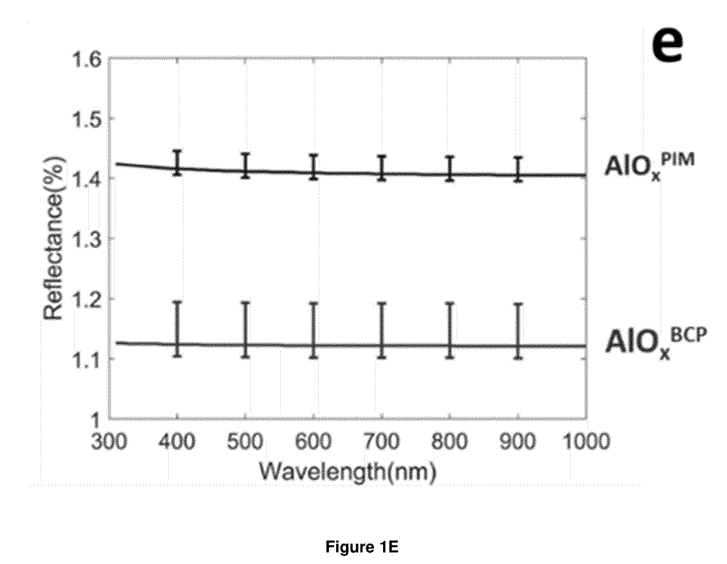

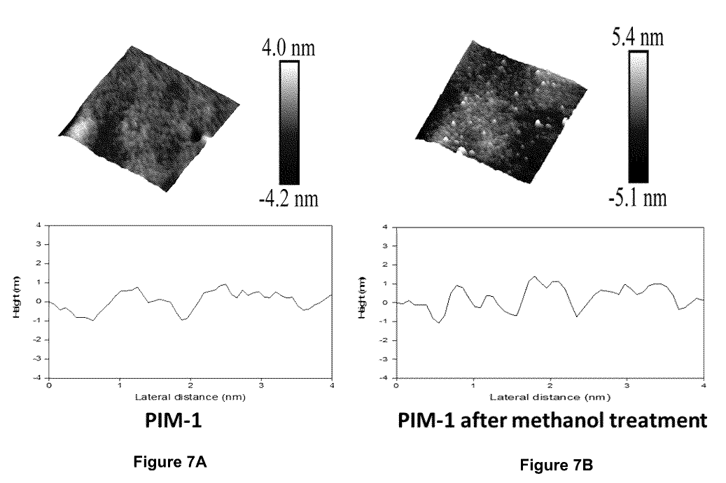

Results: Referring to FIG. 1A, AFM analysis showed that the PIM-1 spin-coated films on the substrates had sub-nm roughness and some ordering of the structure. Referring to FIGS. 1B and 7, the morphology of the PIM-1 film was changed after the methanol treatment, which resulted in increased roughness and loss of structural ordering in the polymer template. Without intending to be bound by theory, it is believed that the methanol treatment resulted in densification of some structural elements of PIM-1 into sphere-like aggregates, thereby increasing the free spaced dispersed within the volume of the polymer. The transformations were on the order of sub-nm length scales and not expected to affect the optical properties of the material in the visible part of the optical spectrum.

Referring to FIG. 1C, the QCM data demonstrated that methanol treatment may also have been associated with mass loss of PIM-1 in methanol that can be attributed to the removal of small amounts of oligomers or solvents (chloroform) trapped in the polymer matrix.

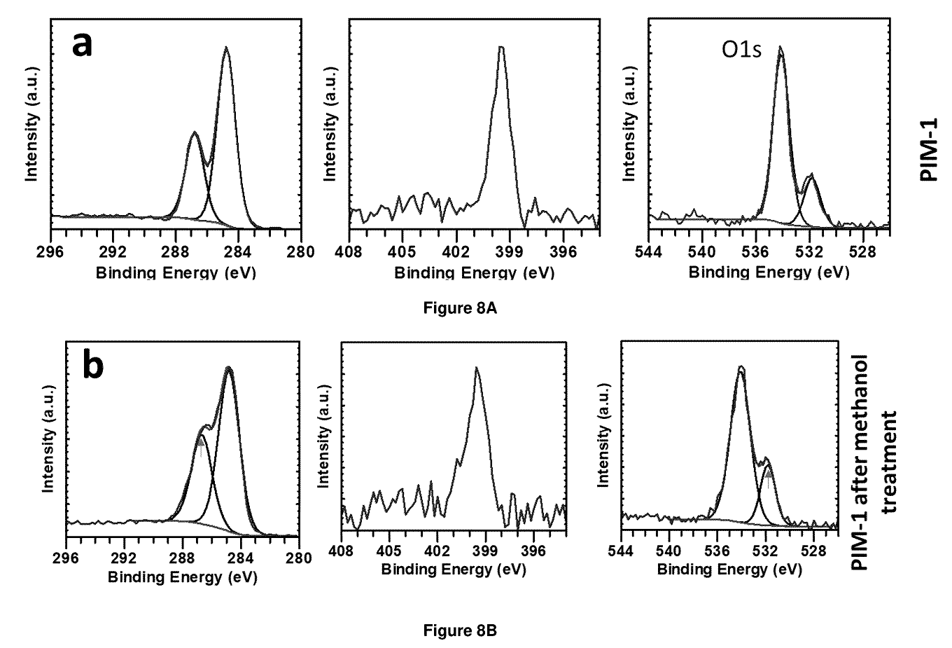

Methanol treatment was found to result in improved infiltration efficiency with TMA, with thicker AlOₓ films formed after polymer removal. Referring to FIG. 8, XPS analysis indicated that a small amount of methanol molecules were trapped in the structure of the PIM-1 film after treatment. The entrapped methanol was found to facilitate the deposition of AlOₓ by providing polar groups for interaction with TMA.

Referring to FIG. 1D, alumina precursors from the infiltration synthesis were found to be intertwined with the PIM polymer chains without forming new chemical bonds, as evidenced by the lack of a shift of peak positions in the FTIR data after 10 SIS cycles. In contrast, with BCP templates, the peak positions corresponding to C═O and —C—O—R groups in polar domains of BPCS were found to shift after exposure of the BCP to the vapors of the metal precursors, which indicates the formation of chemicals bonds with TMA. Without intending to be bound by theory, in the coatings of the disclosure, it is believed that TMA interacts with the CEN bonds of the PIM polymer with TMA molecules. It is believed that metal oxide clusters could percolate throughout the hybrid structure without the formation of chemical bonds with PIM-1 polymer via nucleation of semi-permanent metal-organic adducts of metal oxide precursors with the CEN groups of the PIM polymer. Upon water exposure in the second half of the SIS cycle, the aluminum oxide clusters were formed and became unbonded from the CEN bonds still forming a porous scaffold of AlOₓ. 10 cycles of SIS were found to be sufficient to achieve the desired optical and mechanical properties in the final alumina conformal coating.

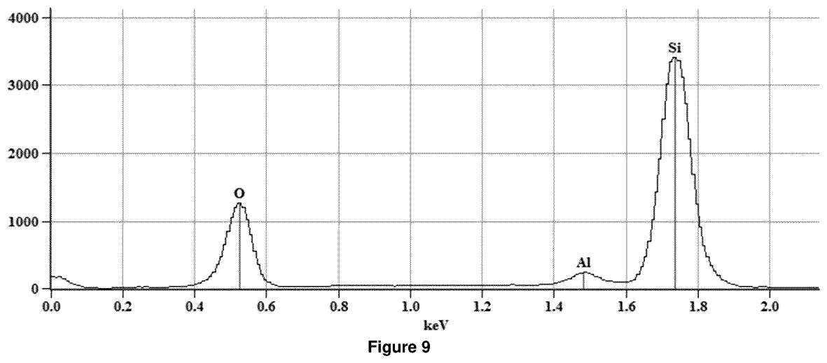

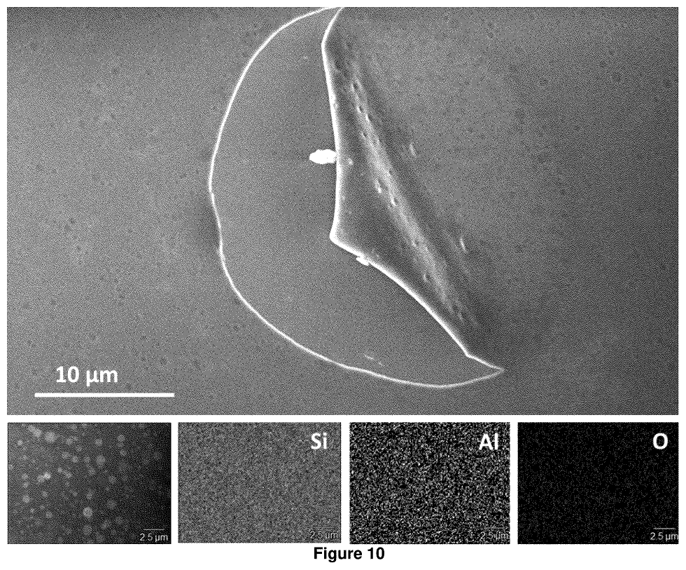

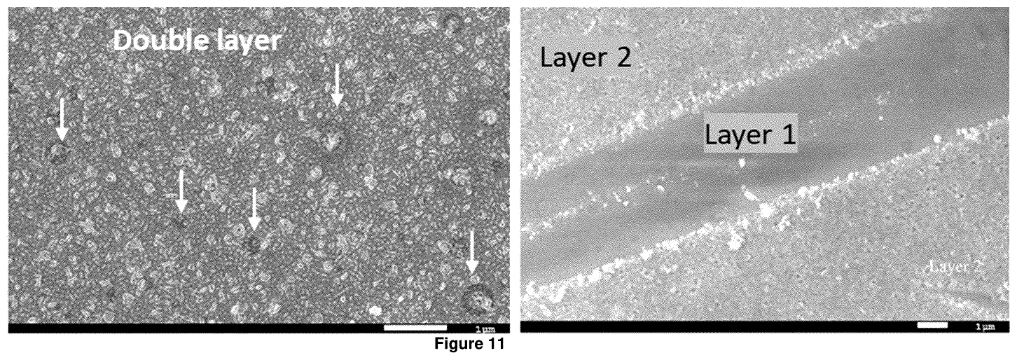

FIGS. 2 and 9 show the porous AlOₓ scaffold after annealing to remove the PIM-1 polymer template. The final porosity of the alumina film after 10 SIS cycles was about 50%. The alumina film had a thickness of about 80 nm, as estimated by ellipsometry. Referring to FIG. 3A, SEM images showed that the alumina films deposited on silicon substrate was smooth. SAXS data showed that the AlOₓ scaffold had a mesoscale poorly ordered structure (FIG. 3E). A very broad peak at the high Q region was observed, suggesting the presence of spherical features of about 10 nm with a broad size distribution, which was consistent with the SEM data. Referring to FIGS. 3D and 10, darker circular features are shown in the SEM images, corresponding to areas that were slightly deflated during the polymer removal via thermal annealing. EDS mapping data showed a uniform distribution of Al and O (FIG. 10). An analysis of delaminated fragments was the AlOₓ films was also done by SEM and confirmed that the coating was a uniform porous coating.

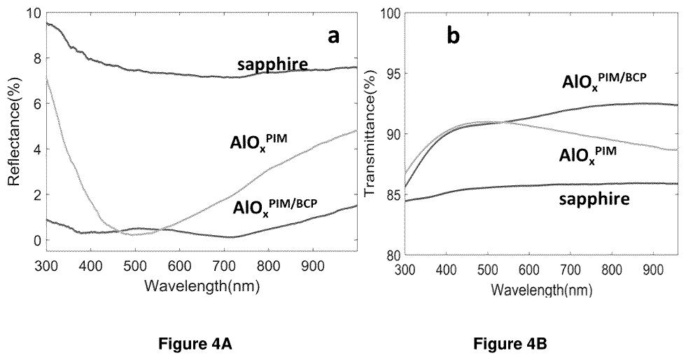

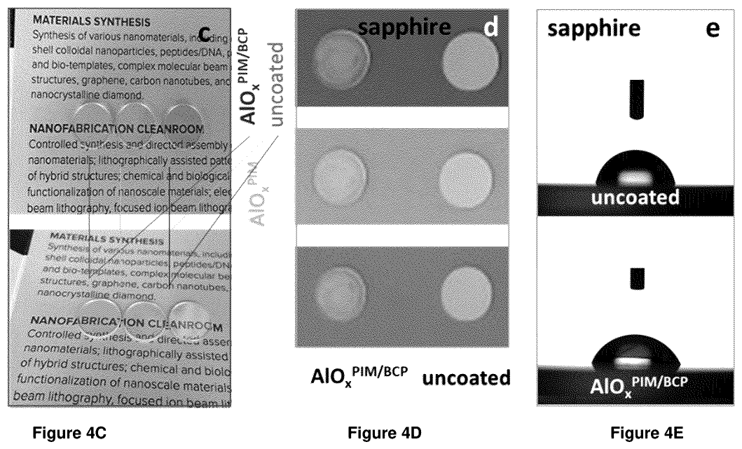

The refractive index of the 80 nm porous alumina single layer coating made in accordance with the disclosure having a porosity of 50% was about 1.41 in the spectral range between 300 and 1000 nm (FIG. 1E). Such a refractive index is well suited to minimize the reflectance for high refractive index substrate such as sapphire (n=1.768) or ITO glass (n=1.827). Referring to FIG. 4, the reflectance of sapphire was lowered from about 7.9% to 0.1% at 500 nm by the presence of a porous alumina coating in accordance with the disclosure only on one side of the sapphire, while the transmittance increased from about 85% to more than about 90-91% in the spectral range between 380 and 650 nm (FIG. 4A).

Double layer coated substrates were prepared with a bottom layer being the 50% porous alumina coating prepared in accordance with the disclosure using the PIM-1 template and a second porous layer formed using BCP as a template formed on top thereof. Layer 1, the porous coating in accordance with the disclosure formed using the PIM-1 template, had a thickness of about 80 nm. Layer 2, the porous BCP-template formed layer, was formed on Layer 1 and had a thickness of about 105 nm. Referring to FIG. 3, the alumina coating obtained using the BCP template was porous tubular micelles. The alumina coating obtained using the BCP template was a denser coating when formed onto of the coating formed in accordance with the disclosure using the PIM-1 template as compared to a BCP template formed coating on a native Si substrate.

The second, BCP template formed, layer had a porosity of about 85% as estimated by ellipsometry. SAXS data indicated that by being deposited on the porous coating in accordance with the disclosure, the porous coating formed from the BCP template had a lower degree of ordering as compared to a BCP template formed coating directly on a Si substrate. While the structure of the BCP template formed coating grown directly on Si has poorly ordered cylinders with local two-dimensional hexagonal lattice and unit cells of about 81.5 nm, the SAXS spectrum of the BCP template formed coating grown on top of a porous coating in accordance with the disclosure had much less pronounced, lower intensity higher-order peeks. Some traces of ordering could still be found in the double layer alumina coating and the lattice constant of the structure was estimated to be about 97.5 nm.

According to the quarter wavelength optimized thickness theory for ARC, the double layer coating should enable destructive interference for the wavelengths in the visible range. The double layer structure provided a graded-index ARC that lowered the reflectance of a sapphire substrate from 7.9% to 0.5% in a broad spectral range (FIG. 4A). The reflectance of sapphire was lowered down to 0.1% at about 700 nm. The light transmission of sapphire was increased from about 85% to about 91-93% as a result of the double layer coating deposited on one side of the sapphire. This was a surprisingly significant reduction of the reflectance and increase in the transparency for a two gradient index layer coating with a total thickness of less than 200 nm.

FIGS. 4C and 4D show photographs of the uncoated and coated sapphire glass, illustrating the performance of the single-layer and gradient index double layered coatings, showing both better transparency and fewer reflections of the sapphire when coating with the ARCs.

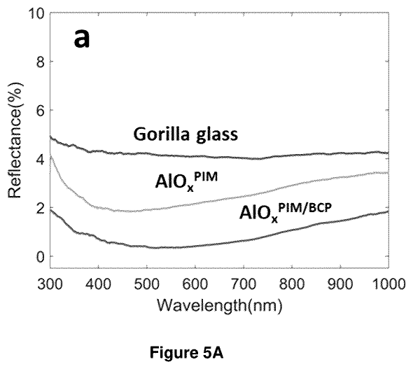

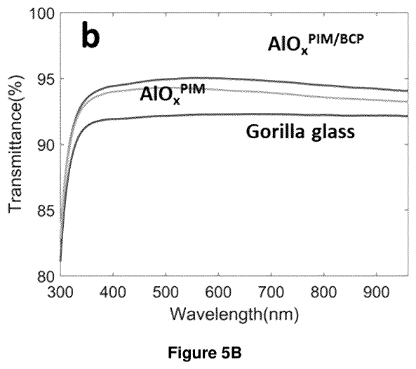

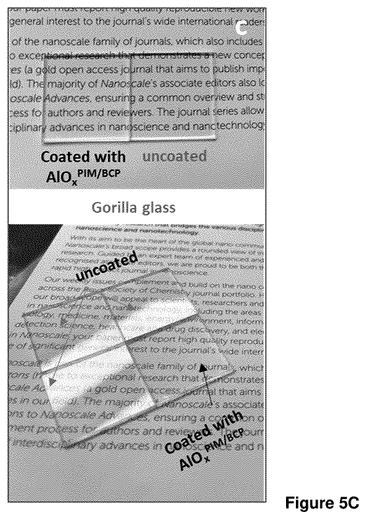

Double layer coatings in accordance with the disclosure were produced as described in this example, but with using Gorilla glass as the substrate. Gorilla glass has a refractive index of 1.50 and is one of the commonly used commercial glass substrates for high-performance screens. The double layer coating resulted in a significant reduction of the reflectance at normal incidence from 4% to below 0.8% over the visible range (FIG. 5A). The transmittance was improved from 92% to about 95% in the visible range with a single side coating of the double layer coating (FIG. 5B). Referring to FIG. 5C, optical images of the coated Gorilla glass show that the samples had good transparency and light reflection was eliminated. No reflection of light was seen with the coated Gorilla glass samples, while the uncoated samples demonstrated pronounced reflection.

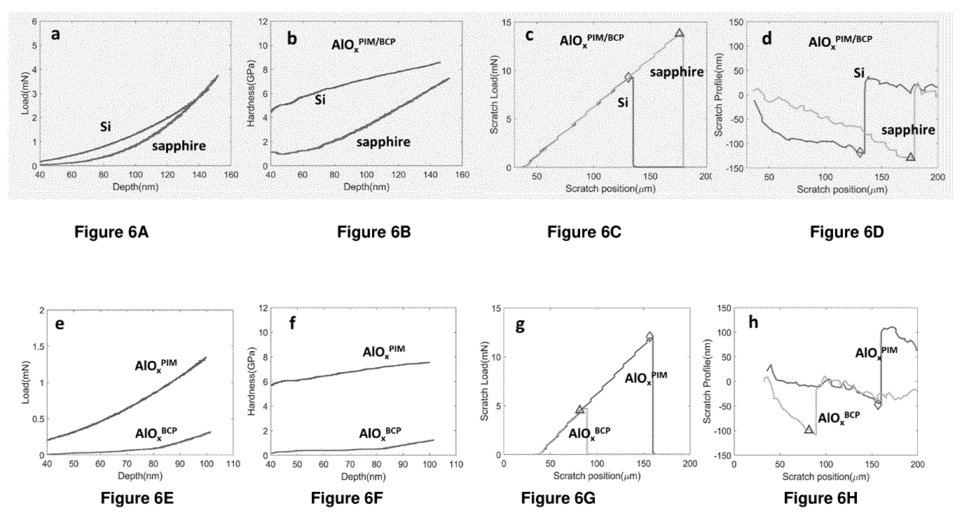

The coatings of the disclosure also demonstrated good mechanical properties, providing protection against scratches and abrasion. Referring to FIG. 6, the coatings of the disclosure, both the single layer PIM-1 template formed coatings and the double-layer coating demonstrated improved mechanical properties as compared to a BCP-template formed coating alone. The hardness of the double layer ARC on sapphire at a nanoindentation of 150 nm was up to 7.5 GPa (FIG. 6B), which is higher than the hardness of bulk fused silica glass (about 6 GPa). The alumina coatings prepared in accordance with the disclosure using the PIM-1 template had a much higher hardness as compared to the alumina coating formed using the BCP template. The single layer PIM-1 template formed coating was comparable to the hardness of the double layer coating.

Sapphire has a bulk reported hardness between 18 GPa and 22 GPa. At smaller loads, the alumina coating deposited on sapphire showed higher tendency towards its deformation, as evidenced by the lower hardness, as compared to an alumina coating deposited on Si (FIG. 6B). A higher loadings, the hardness value of the alumina coating on both sapphire and Si became more similar. Without intending to be bound by theory, it is believed that this is associated with the position of the sharp Berkovich-type indenter with respect to the pores in the top layer and orientation of the pores. Evaluation of hardness is generally recommended to be done on samples in which the deformation takes place only in the top 10-20% of the volume. This is not a possible constraint, however, for the coatings tested herein, which have a thickness below 200 nm. The reduced thickness is beneficial to the optical performance and needs of the optical glass applications.

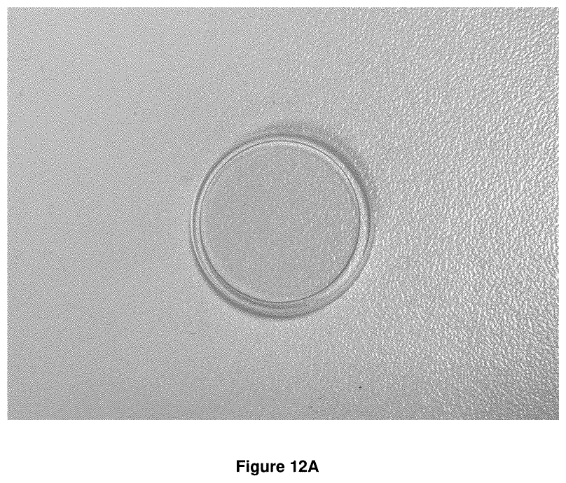

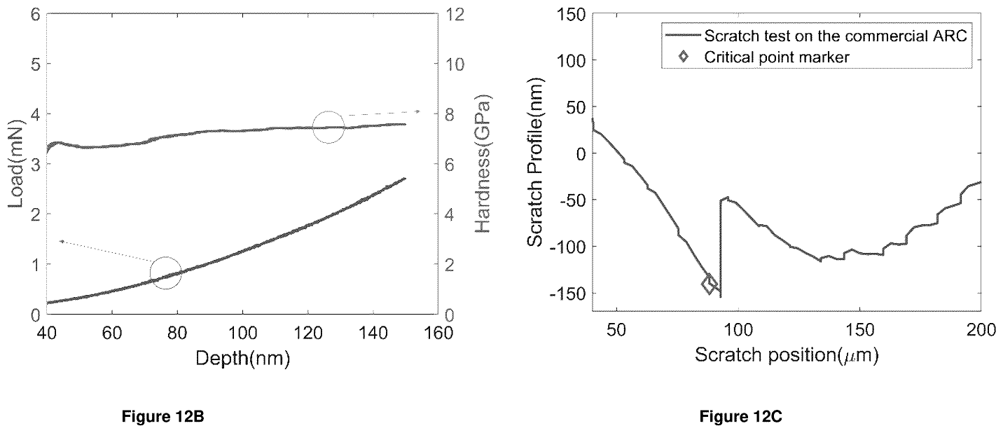

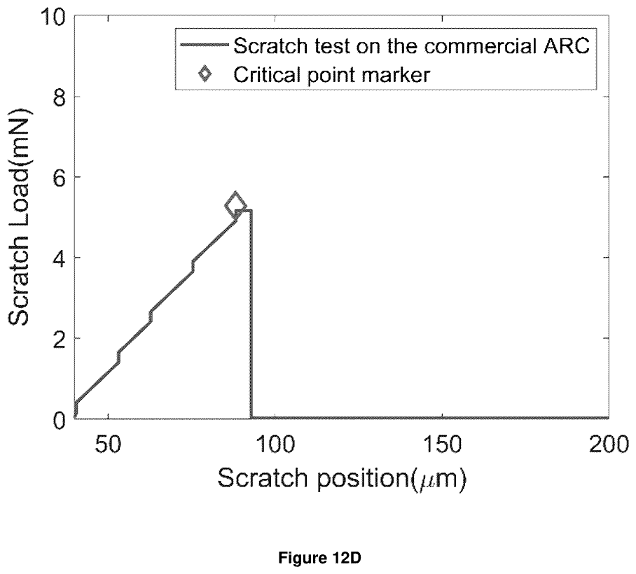

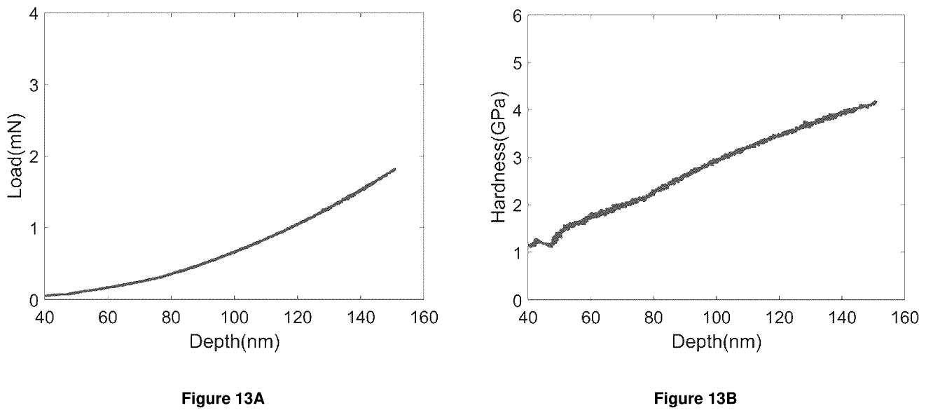

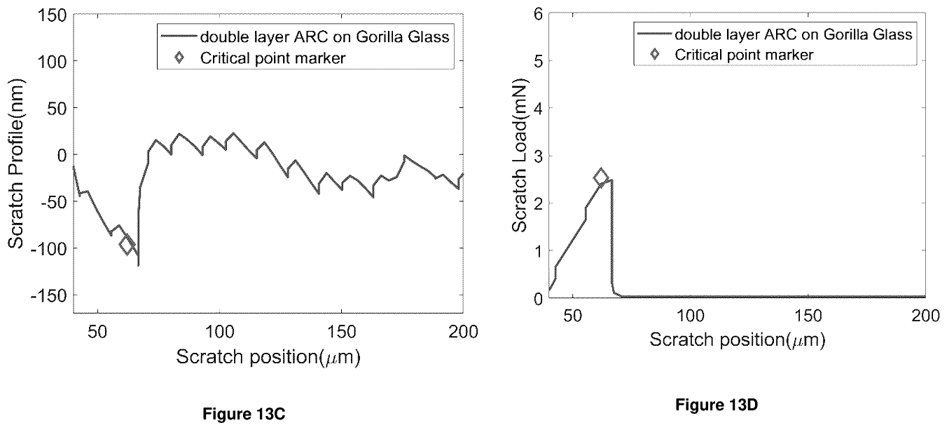

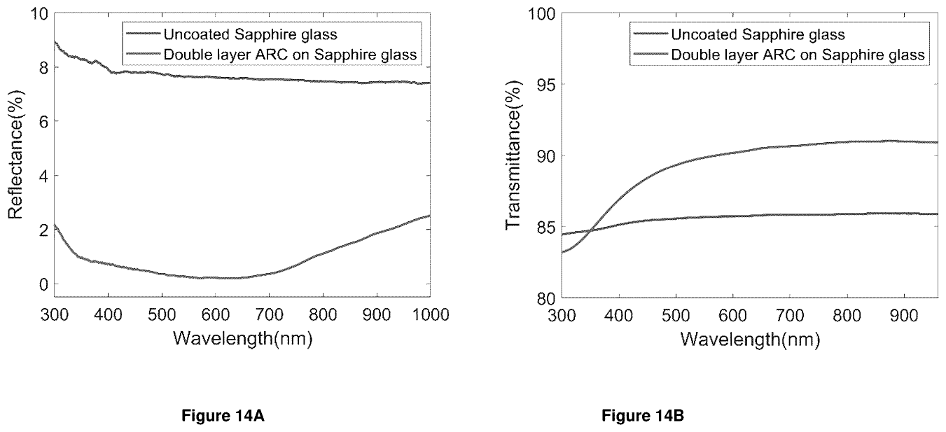

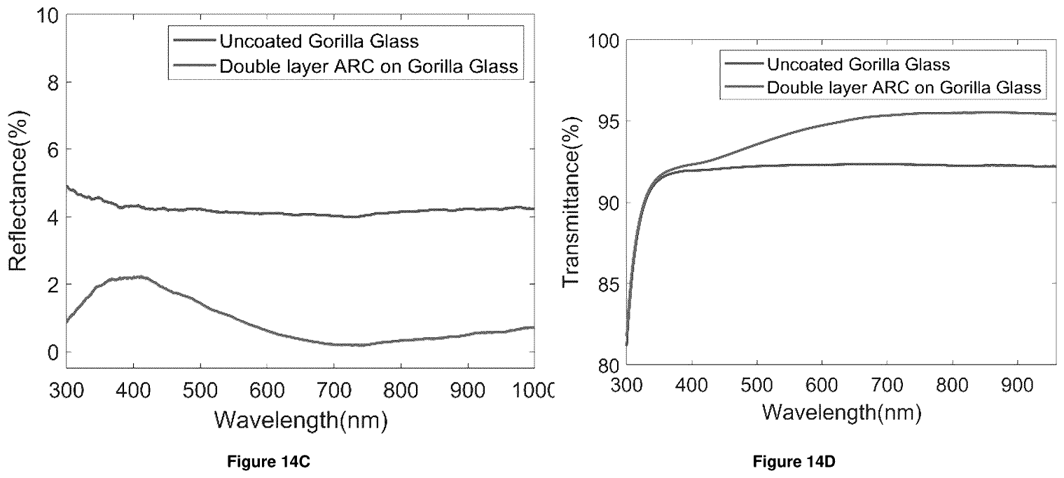

Referring to FIG. 6C, the scratch load during scratching testing is shown. The critical load serves as a measure to compare the scratch resistivity of different coatings when the experimental parameters are kept constant. The maximum load was detected by the instrument using acoustic emission feedback picked by a piezoelectric detector arranged next to the indenter. Referring to FIG. 6D, the maximum load reached was 13 mN with a scratch depth of about 130 nm. This is a significant improvement over a conventional coating, such as a porous anodic aluminum oxide (AAO) ARC coating, in which the indenter can penetrate down to 350 nm at a 2 nM load. This was also approximately two times better than achieved for optical coatings on commercial lenses tested (FIG. 12). Mechanical data for coatings in accordance with the disclosure formed on Gorilla glass are shown in FIG. 13.

A higher scratch resistivity was observed for the coatings in accordance with the disclosure disposed on sapphire substrates as compared to Si (FIGS. 6C and 6D). Without intending to be bound by theory, it is believed that this is a result of the double layer coating and sapphire having similar chemical compositions that results in better adhesion of the coating as compared to the single layer coating. Without intending to be bound by theory, it is believed that the higher hardness and scratch resistance of the PIM-1 template formed coatings of the disclosure as compared to BCP-template formed coatings is attributable to the PIM-1 formed coatings having lower porosity and smaller pore size. In the double layer structure, it is believed that PIM-1 formed coating serves as both an anti-reflective coating and a mechanical supporting layer for the BCP-template formed layer.

It was further observed that the double layer coatings while hydrophilic when formed could be hydrophobized by hexamethyldisilazane (HDMS) treatment. As illustrated in FIG. 4E, the HDMS treatment almost entirely restores the coated substrate to have a contact angle of the uncoated hydrophobic sapphire substrate. In particular, the contact angle of water droplet on sapphire was about 85°, while the contact angle of water droplet on the HDMS double layer coated sapphire was about 75°.

The use of the “a” or “an” are employed to describe elements and components of the embodiments herein. This is done merely for convenience and to give a general sense of the description. This description should be read to include one or at least one and the singular also includes the plural unless it is obvious that it is meant otherwise.

Still further, the figures depict embodiments for purposes of illustration only. One of ordinary skill in the art will readily recognize from the following discussion that alternative embodiments of the structures and methods illustrated herein may be employed without departing from the principles described herein.

Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

1. A process for forming an inorganic porous coating on a substrate, comprising:
forming a polymer template having a plurality of pores comprising applying a thin film of a polymer of intrinsic microporosity on the substrate; and
performing an infiltration cycle comprising:
infiltrating the pores of the polymer template with a first vapor comprising a coating precursor material, wherein the coating precursor material is a precursor for forming an inorganic coating material and the coating precursor material binds to functional groups of the polymer template, and
infiltrating the pores of the polymer template having the coating precursor material bound thereto with a second vapor comprising a precursor reactant, wherein the bound coating material precursor reacts with the precursor reactant to form the inorganic coating material arranged to form the porous inorganic coating.

2. The process of claim 1, wherein forming the polymer template further comprises immersing the thin film in a solvent for a solvent treatment time.

3. The process of claim 1, further comprising removing the polymer of intrinsic microporosity after performing the infiltration cycle, thereby leaving the inorganic porous coating on the substrate

4. The process of claim 1, comprising performing from 1 to 20 infiltration cycles.

5. The process of claim 1, wherein the precursor reactant is H₂O.

6. The process of claim 1, wherein the polymer of intrinsic microporosity is PIM-1.

7. The process of claim 1, wherein the thin film of the polymer of intrinsic microporosity has a thickness of about 20 nm to about 200 nm.

8. The process of claim 1, wherein the solvent is one or more of methanol, acetone, and toluene.

9. The process of claim 1, wherein the coating precursor material is one or more of trimethylaluminium (TMA), diethylzinc, tris(dimethylamido)silane, tetrakis(dimethylamido)zirconium, titanium tetrachloride, titanium tetraisopropoxide, nickel(II) acetylacetonate, palladium(II) hexafluoroacetylacetonate, copper bis(2,2,6,6-tetramethyl-3,5-heptanedionate, metallocenes having the formula (C₅H₅)₂M where M is Cr, Fe, Co, Ni, Pb, Zr, Ru, Rh, Sm, Ti, V, Mo, W, or Zn), and half-metallocene having the formula (C₅H₅)M(CH₃)₃ or (CH₃C₅H₄)M(CH₃), wherein M is Cr, Fe, Co, Ni, Pb, Zr, Ru, Rh, Sm, Ti, V, Mo, W, or Zn).

10. The process of claim 1, wherein the inorganic coating has a porosity of about 10% to about 95%.

11. (canceled)

12. (canceled)

13. (canceled)

14. (canceled)

15. (canceled)

16. The process of claim 1, wherein the substrate comprises a preexisting coating layer and the preexisting coating layer is one or more of an optical coating, a metal oxide layer, and a porous coating layer.

17. (canceled)

18. (canceled)

19. A process for forming a multi-layer coating comprising: performing the process of claim 1 to form a first coating layer and repeating the process to form two or more additional coating layers on the first coating layer.

20. (canceled)

21. (canceled)

22. A process for forming a multi-layer coating comprising:
forming a first porous inorganic coating layer on a substrate by the process of claim 1; and
forming at least a second coating layer on the first porous inorganic coating layer.

23. The process of claim 22, wherein forming the second coating layer comprising:
forming a block copolymer polymer template having a plurality of pores on the substrate by applying a thin film of a block copolymer on the first porous inorganic coating layer and exposing the block copolymer thin film to a solvent treatment; and
performing an infiltration cycle on the block copolymer template, comprising
infiltrating the pores of the block copolymer polymer template with a coating precursor material in a vapor phase, wherein the coating precursor material is a precursor for forming an inorganic coating material, and
infiltrating the pores of the block copolymer polymer template having the coating precursor material therein with a precursor reactant in a vapor phase, wherein the coating material precursor reacts with the precursor reactant to form the inorganic coating material arranged to form the second porous inorganic coating on the first porous inorganic coating, the second porous inorganic coating layer having tubular shaped pores.

24. (canceled)

25. (canceled)

26. The process of claim 23, further comprising removing the polymer of intrinsic microporosity before applying the thin film of the block copolymer.

27. The process of claim 23, further comprising removing the block copolymer after performing the infiltration cycle.

28. (canceled)

29. An anti-reflective coating formed by the process of claim 1.

30. A protective coating formed by the process of claim 1.

31. A porous inorganic multilayer coating formed on a substrate, comprising:
a first porous coating layer disposed on the substrate, the first porous coating layer comprising an inorganic oxide material and comprising a plurality of pores distributed substantially uniformly through the coating, the pores having an average pore size of less than about 10 nm as measured by electron microscopy; and
a second porous coating layer formed from a block copolymer template arranged on the coating, wherein the second porous coating layer formed from the block copolymer comprises pores having a tubular pore structure.

32. (canceled)

33. (canceled)

34. The multi-layer coating of claim 31, wherein each of the coating layers has a different porosity.

35.-49. (canceled)
